(19) United States
(12) Patent Application Publication
(10) Pub. No.: US 2026/0173287 A1
(43) Pub. Date: Jun. 18, 2026

(54) ELECTRONIC DEVICE

(71) Applicant: Luxshare Precision Industry Company Limited, SHENZHEN (CN)

(72) Inventor: Shumin Qiu, SHENZHEN (CN)

(73) Assignee: Luxshare Precision Industry Company Limited, SHENZHEN (CN)

(21) Appl. No.: 19/414,887

(22) Filed: Dec. 10, 2025

(30) Foreign Application Priority Data
Dec. 17, 2024 (CN) 202411865414.0
Dec. 17, 2024 (CN) 202411869577.6

(51) Int. Cl. H05K 5/02; H05K 1/02; H05K 5/00; H05K 9/00

(52) U.S. Cl. CPC H05K 5/0247; H05K 1/0215; H05K 1/028; H05K 5/0069; H05K 5/0243; H05K 9/0064; H05K 9/0067; H05K 2201/10083

(57) ABSTRACT

An electronic device includes a housing, a metal decorative member, a mounting bracket, a conductive part, and a flexible circuit board. The metal decorative member is connected in a first mounting through hole on the housing. The mounting bracket is disposed inside the housing. The mounting bracket is provided with a connection through hole. The conductive part is disposed on two sides of the mounting bracket and inside the connection through hole. The flexible circuit board is disposed on a side of the mounting bracket away from the housing and is electrically connected to the metal decorative member through the conductive part, thereby conducting electrostatic discharge generated on the metal decorative member to a grounding point.

### CLAIM OF PRIORITY AND CROSS-REFERENCE TO RELATED APPLICATION(S)

This application claims the benefits of Chinese Patent Application No. 202411869577.6, filed on Dec. 17, 2024, and Chinese Patent Application No. 202411865414.0, filed on Dec. 17, 2024, which are incorporated herein by reference in their entireties.

### BACKGROUND OF THE DISCLOSURE

### 1. Field of the Disclosure

The present disclosure relates to the field of electronic product technology, and particularly to an electronic device.

### 2. Description of the Related Art

Currently, many electronic products use metal decorative members on plastic housings for decoration in pursuit of aesthetics and high quality, but they often overlook the need for grounding the metal decorative members. This may easily lead to electrostatic discharge generated on the metal decorative members damaging internal electronic components, thereby causing serious problems such as crashes or even damage.

### BRIEF DESCRIPTION OF THE DISCLOSURE

In view of this, embodiments of the present disclosure provide an electronic device, which has a simple grounding method, a small number of parts, simplifies the assembly process, and achieves the effect of electrostatic protection.

An embodiment of the present disclosure provides an electronic device, the electronic device comprising: a housing, internally provided with a cavity, the housing being provided with a first mounting through hole; a metal decorative member, connected in the first mounting through hole; a mounting bracket, disposed in the cavity, the mounting bracket being provided with a first connection through hole; a conductive part, disposed on two sides of the mounting bracket and inside the first connection through hole; and a flexible circuit board, disposed on a side of the mounting bracket away from the housing, the flexible circuit board being electrically connected to the metal decorative member through the conductive part.

Optionally, the conductive part comprises a first conductive line, a second conductive line, and a connection conductive line, the first conductive line is disposed on a surface of the mounting bracket close to the housing, the second conductive line is disposed on a surface of the mounting bracket away from the housing, the connection conductive line is disposed on an aperture surface of the first connection through hole and two ends thereof are respectively electrically connected to the first conductive line and the second conductive line, the second conductive line is electrically connected to the flexible circuit board.

Optionally, the housing is provided with a second mounting through hole, the electronic device further comprises an elastic conductive column, the elastic conductive column is installed in the second mounting through hole, two ends of the elastic conductive column respectively contact and are electrically connected to the metal decorative member and the conductive part.

Optionally, the material of the elastic conductive column is conductive silicone or conductive rubber.

Optionally, the mounting bracket comprises a laser forming area and two fixing areas, the first connection through hole is disposed in the laser forming area, the conductive part is disposed in the laser forming area, the two fixing areas are disposed on two sides of the laser forming area and are located on a side of the mounting bracket close to the flexible circuit board.

Optionally, the flexible circuit board comprises a first flexible part and a second flexible part connected to form a T-shape, two ends of the first flexible part are respectively connected to a microphone and an electronic component, an end of the second flexible part close to the first flexible part is provided with an exposed copper area, the exposed copper area is connected and conducted to the conductive part through conductive adhesive, two ends of the first flexible part are respectively adhesively fixed in the two fixing areas.

Optionally, two ends of the mounting bracket respectively protrude with annular protrusions, the annular protrusions enclose to form the fixing areas, the annular protrusions are provided with an opening communicating with the laser forming area.

Optionally, the mounting bracket further comprises two sound pickup holes, located on a side of the mounting bracket close to the housing and respectively correspondingly disposed with the two fixing areas, a second connection through hole is disposed between the sound pickup hole and the fixing area.

Optionally, an inner side of the housing is provided with a plurality of limiting bosses oppositely disposed along a height direction and two limiting plates oppositely disposed along a transverse direction, the plurality of limiting bosses and the two limiting plates enclose to form a mounting area, the mounting bracket is fixed in the mounting area, each limiting plate is formed with a limiting groove, an outer side of the mounting bracket protrudes with an insertion block that cooperatively insert into the limiting groove.

Optionally, the electronic device further comprises a main circuit board disposed in the cavity, the main circuit board is electrically connected to the flexible circuit board, the conductive part is used for discharging electrostatic generated on the metal decorative member through the flexible circuit board and conducting it to a grounding point of the main circuit board, the materials of the housing and the mounting bracket are plastic or rubber.

### BRIEF DESCRIPTION OF THE DRAWINGS

Through the following description of the embodiments of the present disclosure with reference to the accompanying drawings, the above and other purposes, features, and advantages of the present disclosure will become clearer. In the drawings:

FIG. 1 is an exploded schematic diagram of an electronic device according to an embodiment of the present disclosure;

FIG. 2 is a structural schematic diagram of an electronic device according to an embodiment of the present disclosure;

FIG. 3 is a structural schematic diagram of a flexible circuit board according to an embodiment of the present disclosure;

FIG. 4 is a structural schematic diagram of a mounting bracket according to an embodiment of the present disclosure;

FIG. 5 is a structural schematic diagram of a mounting bracket from another perspective according to an embodiment of the present disclosure;

FIG. 6 is a structural schematic diagram of a housing according to an embodiment of the present disclosure;

FIG. 7 is a structural schematic diagram of a conductive part according to an embodiment of the present disclosure.

### DETAILED DESCRIPTION OF EMBODIMENTS OF THE DISCLOSURE

The present application is described based on embodiments, but the present application is not limited to these embodiments. In the following detailed description of the present application, some specific details are described in detail. Those skilled in the art may fully understand the present application without the description of these details. In order to avoid obscuring the essence of the present application, known methods, procedures, flows, components, and circuits are not described in detail.

Furthermore, those of ordinary skill in the art should understand that the drawings provided herein are for illustrative purposes, and the drawings are not necessarily drawn to scale.

Unless otherwise clearly specified and defined, terms such as “mount”, “connect”, “link”, “fix” should be understood broadly. For example, it may be a fixed connection, a detachable connection, or integrated into one; it may be a mechanical connection, an electrical connection; it may be a direct connection, or an indirect connection through an intermediary, it may be the internal communication between two components or the interaction relationship between two components, unless otherwise clearly defined. Those of ordinary skill in the art may understand the specific meanings of the above terms in the present application according to the specific situation.

Unless the context clearly requires otherwise, throughout the description and the claims, the words “comprise”, “include” and the like are to be construed in an inclusive sense as opposed to an exclusive or exhaustive sense; that is to say, in the sense of “including but not limited to”.

In the description of the present application, it should be understood that the terms “first”, “second”, etc. are used for descriptive purposes only and cannot be understood as indicating or implying relative importance. In addition, in the description of the present application, unless otherwise specified, “a plurality of” means two or more.

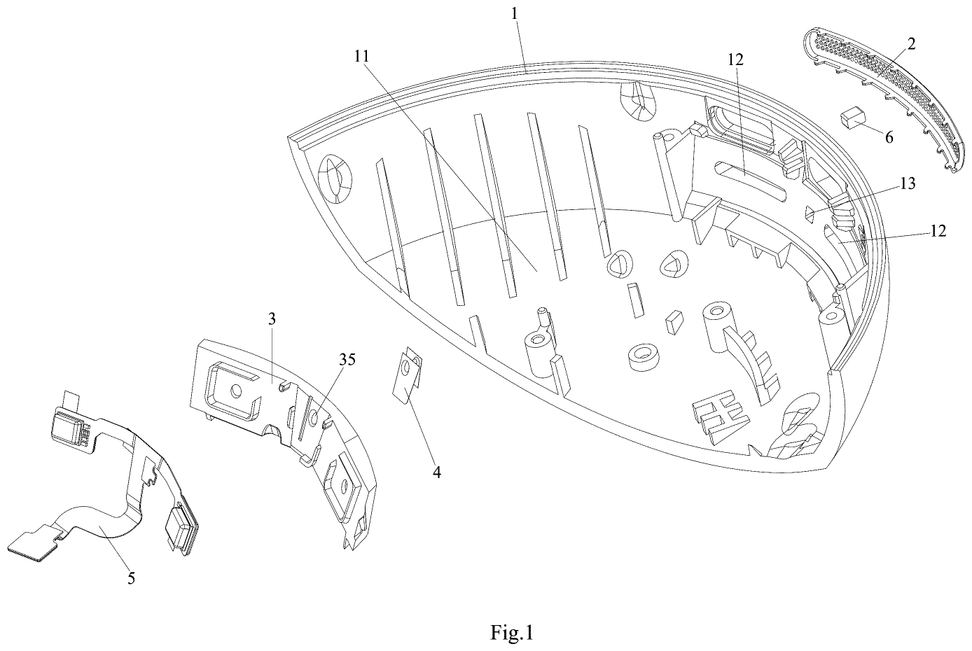

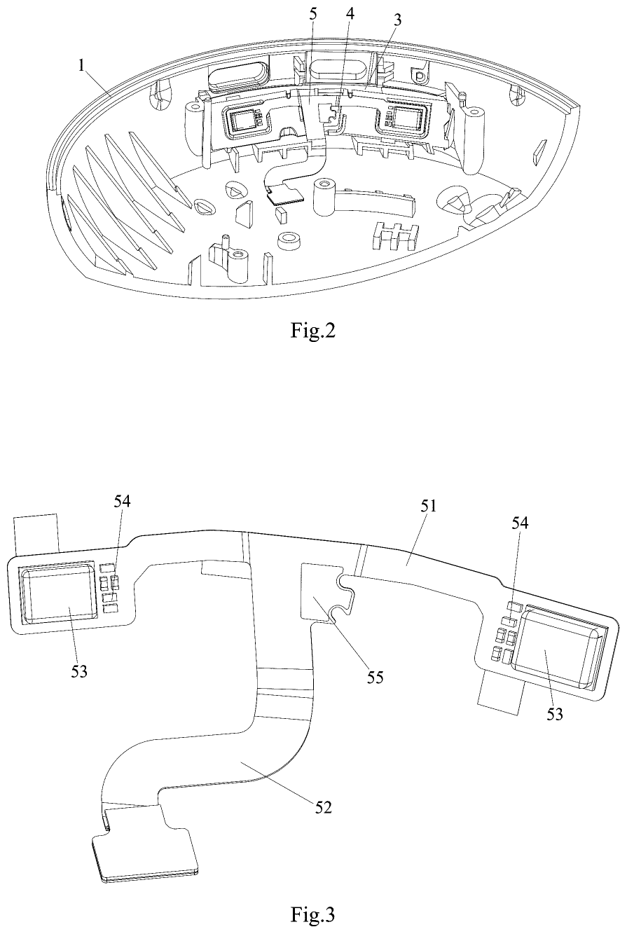

FIG. 1 and FIG. 2 are schematic diagrams of the electronic device of this embodiment. The electronic device may be 3C consumer electronic products such as earphones, watches, headphones, TWS earphones, wristbands, etc. The electronic device includes a housing 1, a metal decorative member 2, a mounting bracket 3, a conductive part 4, a flexible circuit board 5, and a main circuit board, as shown in FIG. 1. The housing 1 is internally provided with a cavity 11 for placing the mounting bracket 3, conductive part 4, flexible circuit board 5, main circuit board, etc.

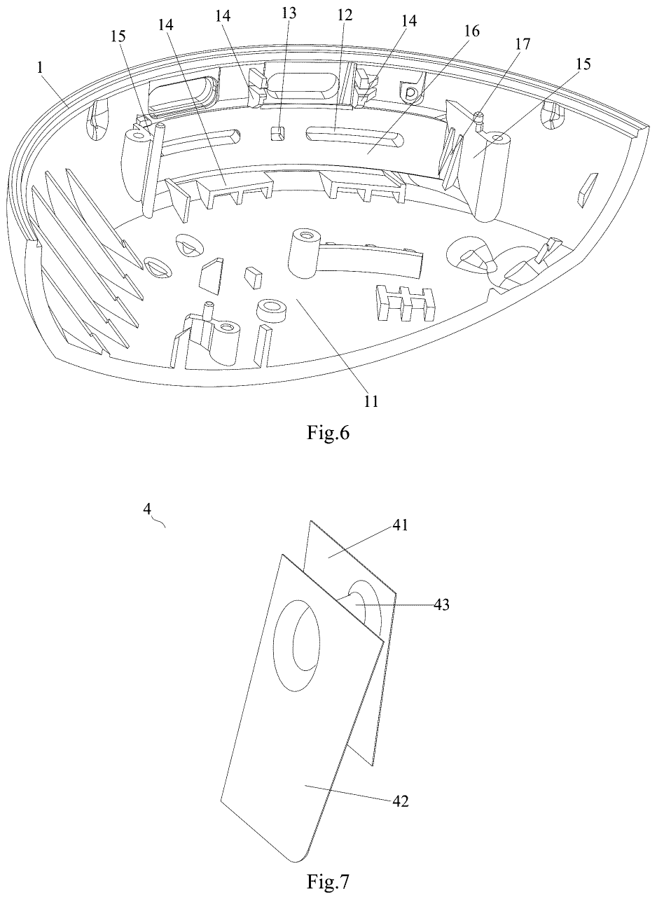

As shown in FIG. 6, the housing 1 is provided with a first mounting through hole 12. The metal decorative member 2 is connected in the first mounting through hole 12, which may improve the aesthetics of the electronic device and other quality requirements, such as acoustic performance. When the electronic device is an earphone, the first mounting through hole 12 may be a vent hole, and the metal decorative member 2 may be a dustproof net; at this time, the first mounting through hole 12 is used to connect the cavity 11 with the external environment, facilitating the inflow and outflow of external air, balancing the internal pressure of the earphone, bringing better auditory effects, and improving the acoustic performance of the earphone; the metal decorative member 2, as a dustproof net, may isolate impurities from the external environment outside the dustproof net, preventing impurities from entering the cavity and affecting the acoustic performance of the earphone.

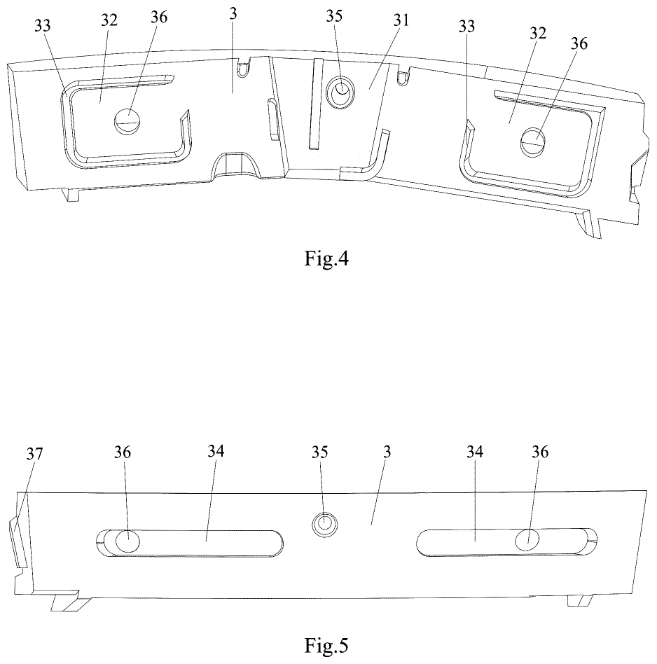

As shown in FIG. 2, the mounting bracket 3 is disposed in the cavity 11 and is relatively fixedly connected to a position corresponding to the metal decorative member 2 on the housing 1. As shown in FIG. 4 and FIG. 5, the mounting bracket 3 is provided with a first connection through hole 35. The conductive part 4 is disposed on two sides of the mounting bracket 3 and inside the first connection through hole 35. As shown in FIG. 2, the flexible circuit board 5 is disposed on a side of the mounting bracket 3 away from the housing 1. The flexible circuit board 5 is electrically connected to the metal decorative member 2 through the conductive part 4. The main circuit board is disposed in the cavity 11. The main circuit board is electrically connected to the flexible circuit board 5. When the electronic device is in use or under test, electrostatic generated on the metal decorative member 2 is discharged through the conductive part 4 and the flexible circuit board 5 to the grounding point of the main circuit board, thereby leading it to the ground, so that it will not cause damage to other electronic components inside the electronic device, improving the safety of the electronic device.

As shown in FIG. 7, the conductive part 4 includes a first conductive line 41, a second conductive line 42, and a connection conductive line 43. Among them, the first conductive line 41 is disposed on a surface of the mounting bracket 3 close to the housing 1 and is used for contacting and connecting with the metal decorative member 2; the second conductive line 42 is disposed on a surface of the mounting bracket 3 away from the housing 1 and is used for electrically connecting with the flexible circuit board 5; the connection conductive line 43 is disposed on an aperture surface of the first connection through hole 35 and two ends thereof are respectively electrically connected to the first conductive line 41 and the second conductive line 42. Thus, electrostatic generated on the metal decorative member 2 may be conducted through the conductive part 4 to the flexible circuit board 5, and the flexible circuit board 5 conducts it to the grounding point of the main circuit board, thereby leading it to the ground, avoiding damage to the electronic device caused by electrostatic.

Exemplarily, the conductive part 4 is formed on two sides of the mounting bracket 3 and inside the first connection through hole 35 using Laser Direct Structuring (LDS) technology. That is, Laser Direct Structuring (LDS) technology is used to create metal traces on two side surfaces of the mounting bracket 3 and inside the first connection through hole 35, thereby forming the first conductive line 41 and the second conductive line 42 on the side surfaces of the mounting bracket 3 and forming the connection conductive line 43 inside the first connection through hole 35.

Among them, the LDS process uses a computer to control the movement of the laser according to the trajectory of the conductive pattern, irradiates the laser onto the mounting bracket 3, and uses laser engraving technology to directly perform metallization plating on the mounting bracket 3 to form metal lines. Using the LDS process to form the conductive part 4 on two side surfaces of the mounting bracket 3 and inside the first connection through hole 35 includes, for example, the following steps:

Injection molding: under certain temperature and pressure, liquid material is injected into a mold on an injection molding machine to form the mounting bracket 3. The material of the mounting bracket 3 is, for example, thermoplastic plastic. Laser: Use laser engraving process on the mounting bracket 3 to form the circuit pattern. Plating: Plate a 5˜8 micron circuit, such as copper, nickel, etc., on the surface of the above circuit pattern as the conductive part 4. Finally, assemble the mounting bracket 3 with the conductive part 4 formed on its surface into the housing 1.

The electronic device provided by the embodiment of the present application uses the LDS process to form the conductive part on the mounting bracket, making the connection between the conductive part and the mounting bracket more stable and less prone to falling off, while not occupying the internal space of the electronic device, which is beneficial for the miniaturization of the electronic device.

As shown in FIG. 4 and FIG. 5, the mounting bracket 3 includes a laser forming area 31 and two fixing areas 32. The first connection through hole 35 is disposed in the laser forming area 31. The two fixing areas 32 are disposed on two sides of the laser forming area 31. The conductive part 4 is formed in the laser forming area 31 through the LDS process. The two fixing areas 32 are disposed on a side of the mounting bracket 3 close to the flexible circuit board 5. The two fixing areas 32 are used for fixing the flexible circuit board 5.

In this embodiment, two ends of the mounting bracket 3 respectively protrude with annular protrusions 33. The annular protrusions 33 enclose to form the fixing areas 32. The annular protrusions 33 are provided with openings communicating with the laser forming area 31, as shown in FIG. 4. The fixing areas 32 formed by the enclosure of the annular protrusions 33 may better fix two ends of the flexible circuit board 5, and their shape matches the structure of two ends of the flexible circuit board 5. The openings of the annular protrusions 33 allow the entire flexible circuit board 5 to be connected to the mounting bracket 3, maintaining flatness and installation stability. Two ends of the flexible circuit board 5 may be pasted in the fixing areas 32 by adhesive or pressure-sensitive adhesive. The part of the flexible circuit board 5 corresponding to the laser forming area 31 may be fixedly connected and electrically connected to the conductive part 4 formed in the laser forming area 31 by laser welding or conductive adhesive bonding, thereby achieving the assembly of the flexible circuit board 5 and the mounting bracket 3.

In this embodiment, the flexible circuit board 5 includes a first flexible part 51 and a second flexible part 52 connected to form a T-shape. Two ends of the first flexible part 51 are respectively connected to a microphone 53 and an electronic component 54. An end of the second flexible part 52 close to the first flexible part 51 is provided with an exposed copper area 55, as shown in FIG. 3. Two ends of the first flexible part 51 form rectangular structures, on which the microphone 53 and the electronic component 54 are respectively disposed, used to achieve specific electronic functions, such as collecting and processing sound in devices like phones, watches, etc., for voice command recognition, calls, etc. The rectangular structures formed at two ends of the first flexible part 51 are consistent with the shapes of the fixing areas 32 formed by the enclosure of the annular protrusions 33, to ensure that the first flexible part 51 provided with the microphone 53 and the electronic component 54 may be flatly installed on the mounting bracket 3. Optionally, two ends of the first flexible part 51 are pasted in the fixing areas 32 by adhesive or pressure-sensitive adhesive. The end of the second flexible part 52 close to the first flexible part 51 is provided with an exposed copper area 55. The exposed copper area 55 is connected and conducted to the second conductive line 42 of the conductive part 4 through conductive adhesive or welding, thereby achieving the electrical connection between the conductive part 4 and the flexible circuit board 5. The other end of the second flexible part 52 extends from below the mounting bracket 3 into the cavity 11 and is electrically connected to the main circuit board, thereby achieving grounding of the metal decorative member and improving the safety performance of the electronic device.

As shown in FIG. 5, the mounting bracket 3 further includes two sound pickup holes 34, located on a side of the mounting bracket 3 close to the housing 1, and the two sound pickup holes 34 are respectively correspondingly disposed with the two fixing areas 32. A second connection through hole 36 is disposed between the sound pickup hole 34 and the fixing area 32. When the mounting bracket 3 is fixedly connected to the housing 1, the two sound pickup holes 34 correspond to the first mounting through hole 12, allowing the two microphones 53 to pick up sound through the second connection through hole 36, the sound pickup hole 34, and the first mounting through hole 12. The sound pickup hole 34 has a long strip structure, which may increase the sound pickup area and improve the sound pickup effect.

Further, the housing 1 is provided with a second mounting through hole 13, as shown in FIG. 6. The electronic device further includes an elastic conductive column 6. The elastic conductive column 6 is installed in the second mounting through hole 13, as shown in FIG. 1. The position of the second mounting through hole 13 corresponds to the laser forming area 31 on the mounting bracket 3, so that two ends of the elastic conductive column 6 respectively contact and are electrically connected to the metal decorative member 2 and the conductive part 4 (i.e., the first conductive line 41). Optionally, the length of the elastic conductive column 6 is slightly longer than the depth of the second mounting through hole 13, so that after the mounting bracket 3, the metal decorative member 2, and the housing 1 are fixedly connected, they may press two ends of the elastic conductive column 6 to compress it, ensuring that the elastic conductive column 6 always maintains contact and electrical connection with the metal decorative member 2 and the conductive part 4. The material of the elastic conductive column 6 is conductive silicone or conductive rubber. Conductive silicone and conductive rubber are materials where conductive particles such as glass coated with silver, aluminum coated with silver, silver, etc., are uniformly distributed in silicone or rubber. Good electrical conductivity is achieved through pressure causing contact between the conductive particles.

In other implementations, the connection method between the metal decorative member 2 and the conductive part 4 may also be selected to use conductive adhesive bonding.

Further, the inner side of the housing 1 is provided with a plurality of limiting bosses 14 oppositely disposed along a height direction and two limiting plates 15 oppositely disposed along a transverse direction. The plurality of limiting bosses 14 and the two limiting plates 15 enclose to form a mounting area 16, as shown in FIG. 6. The first mounting through hole 12 and the second mounting through hole 13 are disposed in the mounting area 16. When the mounting bracket 3 is fixed in the mounting area 16, it may be clamped and fixed by the limiting bosses 14 and the limiting plates 15, preventing incorrect installation positions. Further, each limiting plate 15 is formed with a limiting groove 17. The outer side of the mounting bracket 3 protrudes with an insertion block 37 that cooperatively insert into the limiting groove 17, as shown in FIG. 5 and FIG. 6. When the mounting bracket 3 is installed in the mounting area 16, the insertion block 37 is inserted into the limiting groove 17, which may further fix the mounting bracket 3 and prevent it from falling off. In addition, adhesive may also be provided in the mounting area 16 for pasting with the mounting bracket 3. The structure of the housing 1 and the structure of the mounting bracket 3 described above may ensure the relative positional relationship between various structures and the stability of the connection when the mounting bracket 3 is assembled with the housing 1.

To further improve the safety performance of the electronic device, the materials of the housing 1 and the mounting bracket 3 of the electronic device may be made of insulating materials such as plastic or rubber.

The electronic device of this embodiment includes a housing, a metal decorative member, a mounting bracket, a conductive part, and a flexible circuit board. The metal decorative member is connected in a first mounting through hole on the housing. The mounting bracket is disposed inside the housing. The mounting bracket is provided with a connection through hole. The conductive part is disposed on two sides of the mounting bracket and inside the connection through hole. The flexible circuit board is disposed on a side of the mounting bracket away from the housing and is electrically connected to the metal decorative member through the conductive part, thereby conducting electrostatic discharge generated on the metal decorative member to a grounding point. The grounding method for the metal decorative member in this electronic device is simple, the number of parts is small, the assembly process is simplified, and the effect of electrostatic protection is achieved.

The above descriptions are only preferred embodiments of the present application and are not intended to limit the present application. For those skilled in the art, the present application may have various modifications and changes. Any modifications, equivalent replacements, improvements, etc., made within the spirit and principle of the present application shall be included within the protection scope of the present application.

I/We claim:

1. An electronic device, comprising:
a housing, internally provided with a cavity, the housing being provided with a first mounting through hole;
a metal decorative member, connected in the first mounting through hole;
a mounting bracket, disposed in the cavity, the mounting bracket being provided with a first connection through hole;
a conductive part, disposed on two sides of the mounting bracket and inside the first connection through hole; and
a flexible circuit board, disposed on a side of the mounting bracket away from the housing, the flexible circuit board being electrically connected to the metal decorative member through the conductive part.

2. The electronic device according to claim 1, wherein the conductive part comprises a first conductive line, a second conductive line, and a connection conductive line, the first conductive line is disposed on a surface of the mounting bracket close to the housing, the second conductive line is disposed on a surface of the mounting bracket away from the housing, the connection conductive line is disposed on an aperture surface of the first connection through hole and two ends thereof are respectively electrically connected to the first conductive line and the second conductive line, the second conductive line is electrically connected to the flexible circuit board.

3. The electronic device according to claim 1, wherein the conductive part is formed on two sides of the mounting bracket and inside the first connection through hole using Laser Direct Structuring technology.

4. The electronic device according to claim 1, wherein the housing is provided with a second mounting through hole, the electronic device further comprises an elastic conductive column, the elastic conductive column is installed in the second mounting through hole, two ends of the elastic conductive column respectively contact and are electrically connected to the metal decorative member and the conductive part.

5. The electronic device according to claim 4, wherein a length of the elastic conductive column is longer than a depth of the second mounting through hole.

6. The electronic device according to claim 4, wherein the material of the elastic conductive column is conductive silicone or conductive rubber.

7. The electronic device according to claim 1, wherein the metal decorative member is bonded to the conductive part using conductive adhesive.

8. The electronic device according to claim 1, wherein the mounting bracket comprises a laser forming area and two fixing areas, the first connection through hole is disposed in the laser forming area, the conductive part is disposed in the laser forming area, the two fixing areas are disposed on two sides of the laser forming area and are located on a side of the mounting bracket (3) close to the flexible circuit board.

9. The electronic device according to claim 8, wherein the conductive part is formed in the laser forming area through Laser Direct Structuring process.

10. The electronic device according to claim 8, wherein the flexible circuit board comprises a first flexible part and a second flexible part connected to form a T-shape, two ends of the first flexible part are respectively connected to a microphone and an electronic component, an end of the second flexible part close to the first flexible part is provided with an exposed copper area, the exposed copper area is connected and conducted to the conductive part through conductive adhesive, two ends of the first flexible part are respectively adhesively fixed in the two fixing areas.

11. The electronic device according to claim 8, wherein two ends of the mounting bracket respectively protrude with annular protrusions, the annular protrusions enclose to form the fixing areas, the annular protrusions are provided with an opening communicating with the laser forming area.

12. The electronic device according to claim 11, wherein two ends of the first flexible part form rectangular structures, on which a microphone and an electronic component are respectively disposed.

13. The electronic device according to claim 12, wherein the rectangular structures are consistent with shapes of the fixing areas.

14. The electronic device according to claim 8, wherein the mounting bracket further comprises two sound pickup holes, located on a side of the mounting bracket close to the housing and respectively correspondingly disposed with the two fixing areas, a second connection through hole is disposed between the sound pickup hole and the fixing area.

15. The electronic device according to claim 1, wherein an inner side of the housing is provided with a plurality of limiting bosses oppositely disposed along a height direction and two limiting plates oppositely disposed along a transverse direction, the plurality of limiting bosses and the two limiting plates enclose to form a mounting area, the mounting bracket is fixed in the mounting area.

16. The electronic device according to claim 15, wherein each limiting plate is formed with a limiting groove, an outer side of the mounting bracket protrudes with an insertion block that cooperatively insert into the limiting groove.

17. The electronic device according to claim 1, wherein the electronic device further comprises a main circuit board disposed in the cavity, the main circuit board is electrically connected to the flexible circuit board, the conductive part is used for discharging electrostatic generated on the metal decorative member through the flexible circuit board and conducting it to a grounding point of the main circuit board.

18. The electronic device according to claim 17, wherein the flexible circuit board comprises a first flexible part and a second flexible part connected to form a T-shape, two ends of the first flexible part are respectively connected to a microphone and an electronic component, an end of the second flexible part close to the first flexible part is connected and conducted to the conductive part, another end of the second flexible part away from the first flexible part extends from below the mounting bracket into the cavity and is electrically connected to the main circuit board.

19. The electronic device according to claim 1, wherein the materials of the housing and the mounting bracket are plastic or rubber.

20. The electronic device according to claim 1, wherein the first mounting through hole is a vent hole, and the metal decorative member is a dustproof net.
